(19) United States
(12) Patent Application Publication
(10) Pub. No.: US 2025/0189595 A1
(43) Pub. Date: Jun. 12, 2025

(54) BATTERY INSPECTION AND MANAGEMENT METHOD AND SYSTEM

(71) Applicant: SMART APPROACH CO., LTD., Hsinchu County (TW)

(72) Inventors: Hsin-Lung LIN, Hsinchu County (TW); You Long LAI, Hsinchu County (TW)

(73) Assignee: SMART APPROACH CO., LTD., Hsinchu County (TW)

(21) Appl. No.: 18/972,373

(22) Filed: Dec. 6, 2024

Related U.S. Application Data
(60) Provisional application No. 63/607,540, filed on Dec. 7, 2023.

(30) Foreign Application Priority Data
Nov. 8, 2024 (TW) 113142986

(51) Int. Cl. G01R 31/392; G01R 31/36; G01R 31/367; H01M 10/42; H01M 10/48; H01M 10/54

(52) U.S. Cl. CPC G01R 31/392; G01R 31/3646; G01R 31/367; H01M 10/4285; H01M 10/488; H01M 10/54

(57) ABSTRACT

A battery inspection and management method includes inspecting a target battery at a first time point to generate health inspection data, uploading the health inspection data to a cloud database, determining a classification status of the target battery based on the health inspection data with a preset health range and generating a label for attachment on the target battery, and inspecting the target battery at a second time point later than the first time point to update the health inspection data of the target battery in the cloud database. A battery inspection and management system includes an inspection device, a computing device, and a label printer, wherein the computing device is connected to the inspection device and the label printer.

### CROSS-REFERENCE TO RELATED APPLICATIONS

This non-provisional application claims priority under 35 U.S.C. § 119(a) on Patent Application No(s). 63/607,540 filed in US on Dec. 7, 2023 and Patent Application No(s). 113142986 filed in Republic of China on Nov. 8, 2024, the entire contents of which are hereby incorporated by reference.

### BACKGROUND

### 1. Technical Field

This disclosure relates to a battery management method and system, and more particularly, to a battery inspection and management method and system.

### 2. Related Art

Battery recycling efforts primarily focus on extracting and reusing valuable metals such as cobalt, nickel, lithium, and copper from spent batteries. Conventionally methods include pyro metallurgy, which separates metals through high-temperature heating, and hydrometallurgy, which utilizes acid leaching to dissolve and recover metals from batteries. While these techniques effectively reclaim metal resources, they are associated with high energy consumption and pollutant emissions. In recent years, driven by environmental concerns, technological advancements have shifted toward developing low-energy consumption, low-pollution recycling methods or implementing classification-based battery recycling processes to enhance efficiency and reduce environmental impact.

However, battery inspection and management methods face certain challenges. Conventional inspection approaches are time-consuming and resource-intensive, limiting the data analysis capabilities of battery management systems when handling large volumes of data. Consequently, these systems struggle to quickly classify batteries or accurately assess health status of batteries, posing challenges for applications requiring high precision and reliability.

### SUMMARY

Accordingly, this disclosure provides a battery inspection and management method and system.

According to an embodiment of this disclosure, a battery inspection and management system comprises an inspection device, a computing device and a label printer, wherein the computing device is connected to the inspection device and label printer. The inspection device is configured to inspect a target battery to generate health inspection data; the computing device is configured to upload the health inspection data to a cloud database and determine a classification status of the target battery based on the health inspection data and a preset health range; the label printer is configured to generate a label for attachment on the target battery, wherein the label shows the classification status and configured to link to the health inspection data of the target battery in the cloud database.

According to an embodiment of this disclosure, a battery inspection and management method comprises: inspecting a target battery at a first time point to generate health inspection data; uploading the health inspection data to a cloud database; determining a classification status of the target battery based on the health inspection data and a preset health range, and generating a label for attachment on the target battery, wherein the label shows the classification status and configured to link to the health inspection data of the target battery in the cloud database; and inspecting the target battery at a second time point later than the first time point to update the health inspection data of the target battery in the cloud database.

In view of the above description, the battery inspection and management method and system of the present disclosure enable the sorting and labeling of the recycled battery, and the recycled battery may be reused after classifying of the recycled batteries, thereby enhancing efficiency and reducing environmental impact.

### BRIEF DESCRIPTION OF THE DRAWINGS

The present disclosure will become more fully understood from the detailed description given herein below and the accompanying drawings which are given by way of illustration only and thus are not limitative of the present disclosure and wherein:

FIG. 1 is a block diagram illustrating a battery inspection and management system according to an embodiment of the present disclosure;

FIG. 2 is a block diagram illustrating a battery inspection and management system according to another embodiment of the present disclosure;

FIG. 3 is a flowchart illustrating a battery inspection and management method according to an embodiment of the present disclosure;

FIG. 4 is a flowchart illustrating determining the classification status of a battery according to an embodiment of the present disclosure;

FIG. 5 is a flowchart illustrating determining the classification status of a battery according to another embodiment of the present disclosure;

FIG. 6 is a flowchart illustrating inspecting a battery according to an embodiment of the present disclosure;

FIG. 7 is a flowchart illustrating inspecting a battery according to another embodiment of the present disclosure; and

FIG. 8 is a flowchart illustrating a battery inspection and management method according to another embodiment of the present disclosure.

### DETAILED DESCRIPTION

In the following detailed description, for purposes of explanation, numerous specific details are set forth in order to provide a thorough understanding of the disclosed embodiments. According to the description, claims and the drawings disclosed in the specification, one skilled in the art may easily understand the concepts and features of the present invention. The following embodiments further illustrate various aspects of the present invention, but are not meant to limit the scope of the present invention.

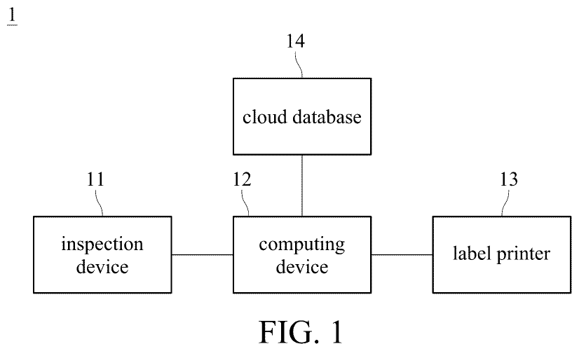

Please refer to FIG. 1, which is a block diagram illustrating a battery inspection and management system according to an embodiment of the present disclosure. As shown in FIG. 1, the battery inspection and management system 1 includes an inspection device 11, a computing device 12, a label printer 13, and a cloud database 14. The computing device 12 is connected to the inspection device 11, the label printer 13 and the cloud database 14 in a wired or wireless manner, wherein the cloud database 14 may serve as an internal database of the battery inspection and management system 1, or as an external database of the battery inspection and management system 1.

The inspection device 11 is configured to inspect a target battery to generate health inspection data. For example, the inspection device 11 may include an internal resistance tester, capacity tester, charge-discharge cycle life tester, voltage detector, temperature monitoring system, battery management system (BMS) testing equipment, BMS data collector, or combinations of one or more thereof. For example, the target battery may include a lithium-ion battery, a nickel-metal hydride battery, a lead-acid battery, or a lithium polymer battery. For example, the health inspection data may include the state of health (SOH), current voltage, charge impedance, voltage drop rate, voltage recovery rate, discharge impedance, usable capacity remained, and/or classification grade, etc.

In an embodiment, the inspection device 11 may be configured to establish a simulation testing procedure based on characteristic specifications of the target battery and execute the simulation testing procedure to generate the health inspection data of the target battery. For instance, the characteristic specifications of battery may be provided by a customer in a specification sheet or obtained from specification data of the battery under test.

The simulation testing procedure may involve the use of a BMS protocol and thirty golden samples for determination. The health inspection data of a battery may include a battery evaluation report, SOH status, and/or classification of battery inspection.

The computing device 12 is configured to upload the health inspection data to the cloud database and determine a classification status of the target battery based on the health inspection data and a preset health range. In an embodiment, the computing device 12 may be a server, a personal computer, a laptop, a smartphone, an industrial computer, a tablet, or a quantum computer, etc., which is capable of uploading the health inspection data to the cloud database 14 and determining whether the classification status of the target battery meets the preset health range. Additionally, the computing device 12 may include one or more processors, the processor is, for example, a central processing unit (CPU), a graphics processing unit (GPU), a microcontroller, a programmable logic controller (PLC), or other processors with signal processing capabilities. In another implementation, the computing device 12 may be one or more of a combination of a computing device of an embedded system or sensor, etc., capable of uploading inspection data to the cloud database, and a computing device of a BMS test diagnostic device, an edge computing device, a battery health monitoring system, a cloud analysis platform, etc., capable of determining whether the classification status of the battery meets the preset health range based on the health inspection data.

In an embodiment, the preset health range indicates that the state of health of the battery is greater than 20%, the classification status indicates reusing when the health inspection data meets the preset health range, and the classification status indicates scrapping when the health inspection data does not meet the preset health range. For example, a battery might be recycled when the state of health of the battery is below 80%, and may have health inspection data between 20% and 80% when the battery is classified as reusable, such battery may be downgraded for reuse in energy storage cabinet, roadside equipment, or uninterruptible power system (UPS).

In an embodiment, when difference between the health inspection data of target battery and health data of a plurality of pre-used batteries of an uninterruptible power system is less than a preset value, the inspection device 12 mark the target battery as applicable for the uninterruptible power system. For instance, when the health data of the pre-used batteries in the uninterruptible power system is 60% and the health inspection data inspected by the inspection device 11 indicates that the state of health of target battery is also 60%, the computing device 12 determines that the difference between the health inspection data of target battery and health data of the plurality of pre-used batteries of the uninterruptible power system is lower than the preset value, and marks the target battery as applicable for the uninterruptible power system. The preset value may be adjusted based on actual requirements and is not limited by this disclosure.

The label printer 13 generates a label for attachment on the target battery, wherein the label shows the classification status and configured to link to the health inspection data of the target battery in the cloud database 14. The generation of a label may be through printing, the label may be a two-dimensional barcode, a three-dimensional barcode, a quick response (QR) code, an antenna, a radio-frequency identification (RFID) tag, and/or an encrypted electric insurance card, among others, and the label may feature different colors or patterns to indicate various classification statuses. For example, a label with a two-dimensional barcode and/or antenna generated by the label printer 13 may be scanned to link to the health inspection data of the battery in the cloud database. When the classification status is “reusing”, the generated label may be green or include a reuse-indicating pattern, and when the classification status is “scrapping”, the label may be red or include a disposal-indicating pattern.

The cloud database 14 is configured to receive the health inspection data uploaded by the computing device 12, and the health inspection data may be linked via the label generated by the label printer 13. For example, the cloud database 14 may include a relational database, a document database, and/or an automated database. The health inspection data of a battery linked via the label to the cloud database 14 may be presented as a table, a graphical file, or a text file. Specifically, the cloud database 14 may be implemented as a Global Standards One (GS1) database.

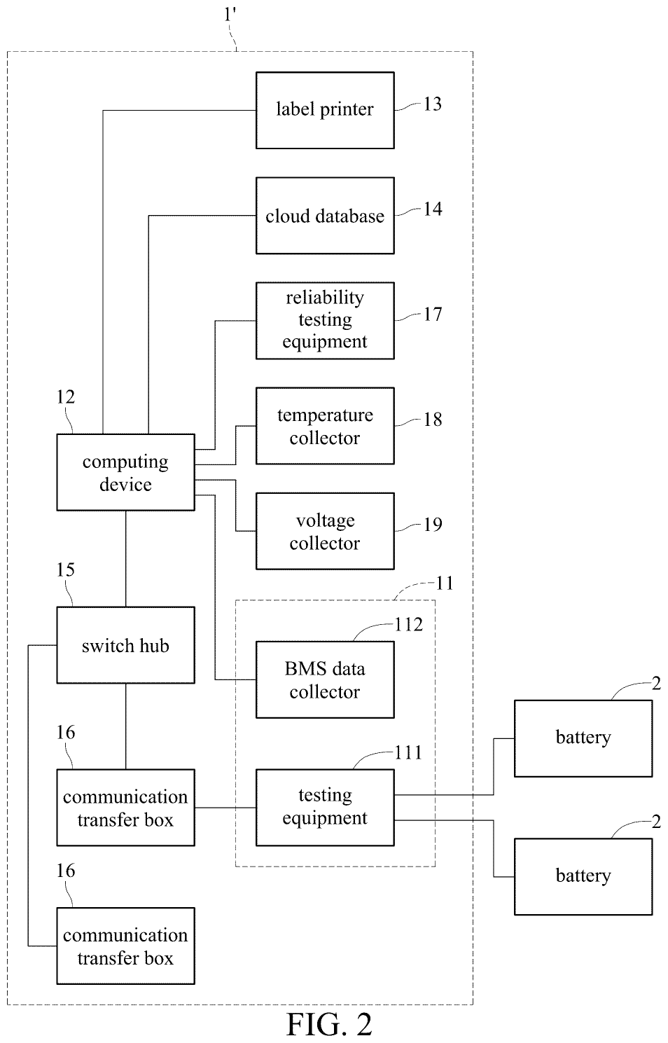

Please refer to FIG. 2, which is a block diagram illustrating a battery inspection and management system according to another embodiment of the present disclosure. As shown in FIG. 2, the battery inspection and management system 1′ includes an inspection device 11, a computing device 12, a label printer 13, a cloud database 14, a switch hub 15, communication transfer boxes 16, reliability testing equipment 17, a temperature collector 18, and a voltage collector 19, wherein the implementation, functions, and connection relationships of the inspection device 11, the computing device 12, the label printer 13, and the cloud database 14 are the same as those in the battery inspection and management system 1 illustrated in FIG. 1, and no further details are described here. In this embodiment, the inspection device 11 of the battery inspection and management system 1′ may include testing equipment 111 and a BMS data collector 112. The testing equipment 111 is connected to the computing device 12 via the switch hub 15 and the communication transfer box 16, and the BMS data collector 112 is connected to the computing device 12. Additionally, the computing device 12 is further connected to the switch hub 15, the communication transfer boxes 16, the reliability testing equipment 17, the temperature collector 18, and the voltage collector 19. In an embodiment, the BMS data collector 112, the reliability testing equipment 17, the temperature collector 18, and the voltage collector 19 may be connected to the computing device 12 in a wired or wireless manner. In another embodiment, additional communication transfer boxes 16 may be disposed between the computing device 12 and the BMS data collector 112, the reliability testing equipment 17, the temperature collector 18, and the voltage collector 19. The battery 2 is connected to the battery inspection and management system 1′ through the testing equipment 111 for testing. The battery 2 may be an energy storage battery for energy cabinets or a power battery for motorcycles, cars, or buses. The communication transfer boxes 16 may be implemented using RS-485 or Ethernet connections. While FIG. 2 schematically illustrates two communication transfer boxes 16 and two batteries 2, the disclosure is not limited to these quantities and may include one or more than two communication transfer boxes and/or batteries. For example, there may be eight communication transfer boxes 16, each connected to the testing device 111. For example, one testing device 111 may simultaneously test up to 64 batteries.

The testing equipment 111 is configured to inspect the battery and generate battery health data. For example, the testing equipment 111 may be rapid test equipment and/or a battery rapid screening system, and may include golden sampling modeling, battery aging model, and state-of-charge (SOC) distribution model, allowing rapid inspection of battery health through intelligent computation. The BMS data collector 112 is configured to collect battery health data. For example, the BMS data collector 112 may be an intelligent battery management module, battery monitoring system, multi-channel data acquisition device, or mobile inspection equipment.

In this embodiment, the switch hub 15 may be configured to connect the computing device 12 to a plurality of communication transfer boxes 16. The communication transfer boxes 16 may be used to connect various devices to the computing device 12. The reliability testing equipment 17 may include an environmental test chamber, electrical durability test equipment, or thermal cycling test equipment, etc. The temperature collector 18 may be a thermocouple, a thermistor, or an infrared temperature sensor, etc. The voltage collector 19 may be a multimeter, a voltage divider, or a wireless voltage sensor, etc. The switch hub 15, the communication transfer boxes 16, the reliability testing equipment 17, the temperature collector 18, and/or the voltage collector 19 are optional components.

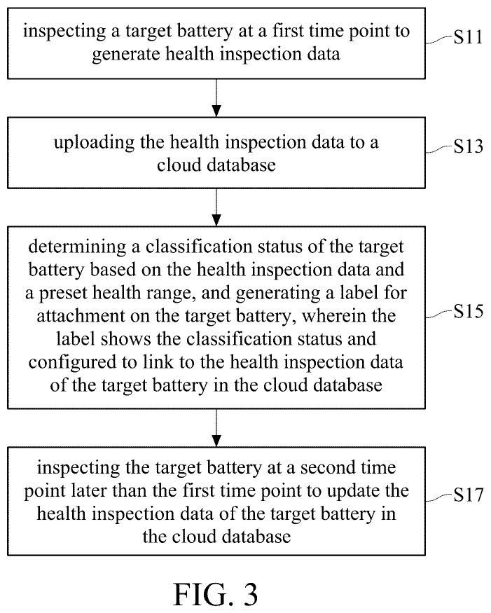

Please refer to FIG. 3, which is a flowchart illustrating a battery inspection and management method according to an embodiment of the present disclosure. As shown in FIG. 3, the battery inspection and management method includes the following steps: step S11: inspecting a target battery at a first time point to generate health inspection data; step S13: uploading the health inspection data to a cloud database; step S15: determining a classification status of the target battery based on the health inspection data and a preset health range, and generating a label for attachment on the target battery; and step S17: inspecting the target battery at a second time point later than the first time point to update the health inspection data of the target battery in the cloud database. The sequence of step S13 and step S15 is not fixed, that is, step S15 may be executed first and then step S13 may be executed, or step S15 and step S13 may be executed at the same time, this disclosure does not impose any restrictions on the execution order. The battery inspection and management method may be applied to the battery inspection and management system 1 shown in FIG. 1 and the battery inspection and management system 1′ shown in FIG. 2. The battery inspection and management method shown in FIG. 3 is explained below by taking the battery inspection and management system 1 shown in FIG. 1 as an example.

In step S11, the inspection device 11 inspects the target battery at the first time point and generates health inspection data. Specifically, the first time point may refer to when the battery arrives at the recycling facility or when the battery is received. The battery may be an energy storage battery for an energy cabinet or a power battery for a motorcycle, a car, or a bus. The health inspection data may include a parameter such as state of health (SOH), current voltage, charging impedance, voltage drop rate, voltage recovery rate, discharge impedance, remaining usable capacity, and classification grade.

In step S13, the computing device 12 uploads the health inspection data of the target battery to the cloud database 14. Specifically, the health inspection data uploaded to the cloud database 14 may be in the form of a table, a graphical file, or a text file. The health inspection data may include the battery serial number, enabling the computing device 12 to create a lookup table in the cloud database 14 that maps the battery serial number to corresponding the inspection value.

In step S15, the computing device 12 determines the classification status of the target battery based on the health inspection data and the preset health range, and generates the label via the label printer 13 to be attached on the target battery. Specifically, the preset health range may indicate that the state of health of the target battery is greater than 20%. The classification status of the battery may indicate either reusing or scrapping. The label may be a two-dimensional barcode, a three-dimensional barcode, a quick response (QR) code, an antenna, a radio frequency identification (RFID) tag, and/or an encrypted electronic security card, among others, and the label may also feature different colors or patterns to show the classification status of the battery.

In step S17, the inspection device 11 inspects the target battery at the second time point, which is later than the first time point, to update the health inspection data in the cloud database for the target battery. Specifically, the second time point may correspond to when the battery is downgraded for reusing in an energy cabinet, roadside equipment, or an uninterruptible power system (UPS), and updating the health inspection data in the cloud database may involve uploading the battery health data to a Global Standards One (GS1) database. Additionally, in another embodiment, when the battery is inspected at the second time point, the classification status may be reassessed based on the health inspection data at the second time point and the preset health range. For instance, the classification status indicates reusing when the health inspection data at the second time point falls within the preset health range, and the classification status indicates scrapping when the health inspection data at the second time point does not meet the preset health range.

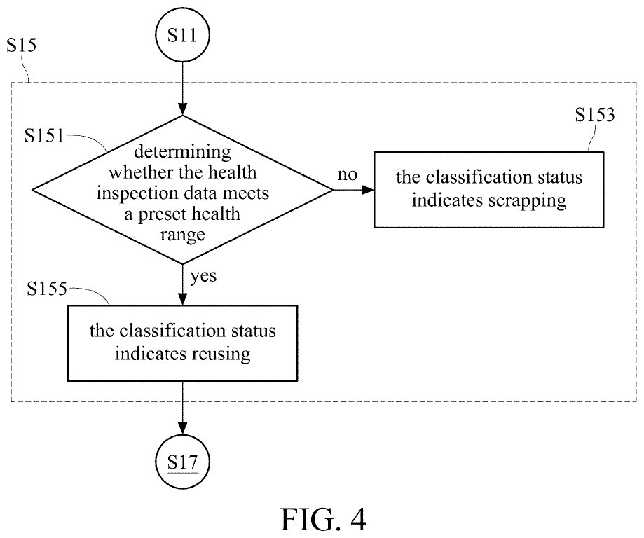

Please refer to FIG. 3 in conjunction with FIG. 4, wherein FIG. 4 is a flowchart illustrating determining the classification status of a battery according to an embodiment of the present disclosure. As shown in FIG. 4, step S15 of FIG. 3 may include step S151: determining whether the health inspection data meets a preset health range; when the determination in step S151 is “No”, indicating that the health inspection data does not meet the preset health range, executing step S153: the classification status indicates scrapping; and when the determination in step S151 is “Yes”, indicating that the health inspection data meets the preset health range, executing step S155: the classification status indicates reusing. The method for determining the classification status of the battery may be applied to the battery inspection and management system 1 shown in FIG. 1 and battery inspection and management system 1′ shown in FIG. 2. The determining the classification status of a battery shown in FIG. 4 is explained below by taking the battery inspection and management system 1 shown in FIG. 1 as an example.

In step S151, the computing device 12 determines whether the health inspection data meets the preset health range. Specifically, the preset health range may indicate that the state of health of the battery is greater than 20%, the health inspection data meets the preset health range when the state of health of the battery is greater than 20%, and the health inspection data does not meet the preset health range when the state of health of the battery is less than or equal to 20%.

In step S153, the label printer 13 generates a label with the classification status indicating scrapping. Specifically, the label generated by the label printer 13 may include a two-dimensional barcode, which may be scanned to link to the health inspection data of the battery stored in the cloud database. When the classification status of battery is scrapping, the label may be red or feature a pattern indicating scrapping.

In step S155, the label printer 13 generates a label with the classification status indicating reusing. Specifically, the label generated by the label printer 13 may include a two-dimensional barcode, which may be scanned to link to the health inspection data of the battery stored in the cloud database. When the classification status of the battery is reusing, the label may be green or feature a pattern indicating reuse.

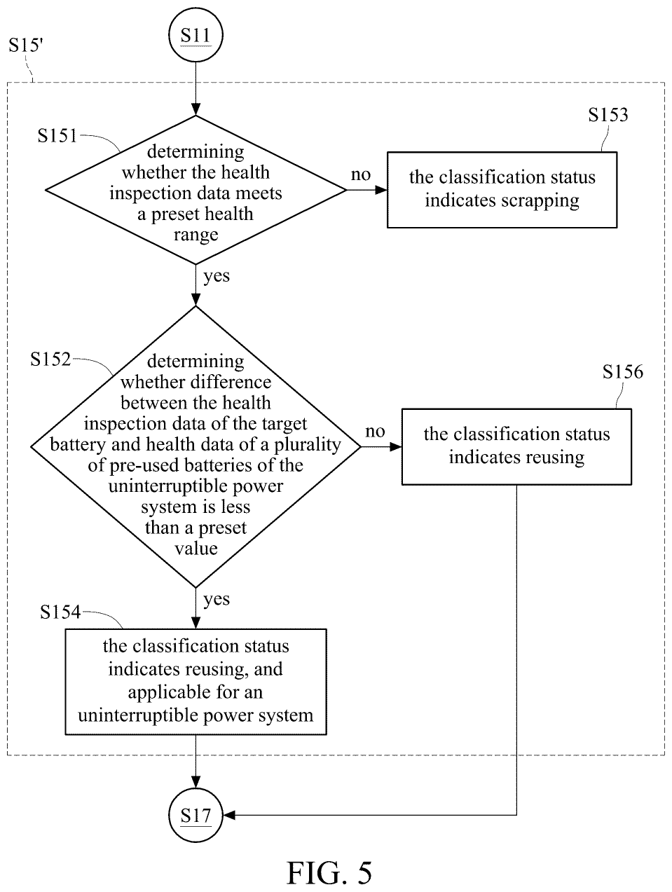

Please refer to FIG. 5, which is a flowchart illustrating determining the classification status of a battery according to another embodiment of the present disclosure. As shown in FIG. 5, step S15′ may include step S151: determining whether the health inspection data meets a preset health range; when the determination in step S151 is “No”, indicating that the health inspection data does not meet the preset health range, executing step S153: the classification status indicates scrapping; when the determination in step S151 is “Yes”, indicating that the health inspection data meets the preset health range, executing step S152: determining whether the difference between the health inspection data of the target battery and health data of a plurality of pre-used batteries of the uninterruptible power system is less than a preset value; when the determination in step S152 is “Yes”, indicating that the difference between the health inspection data of target battery and health data of the plurality of pre-used batteries of the uninterruptible power system is less than the preset value, executing step S154: the classification status indicates reusing, and applicable for an uninterruptible power system; when the determination in step S152 is “No”, indicating that the difference between the health inspection data of target battery and health data of a plurality of pre-used batteries of an uninterruptible power system is not less than the preset value, executing step S156: the classification status indicates reusing. The execution method for steps S151 and S153 are identical to those in FIG. 4 and are not further described herein. The method for determining the classification status of battery may be applied to the battery inspection and management systems 1 and 1′ shown in FIGS. 1 and 2, respectively, and the following example utilizes the battery inspection and management system 1 shown in FIG. 1 to illustrate the determining the classification status of a battery shown in FIG. 5.

In step S152, the computing device 12 determines whether difference between the health inspection data of the target battery and health data of a plurality of pre-used batteries of the uninterruptible power system is less than a preset value. Specifically, for example, the state of health of the pre-used batteries in the uninterruptible power system may be all around 60%, and when the inspection device 11 determines that the health inspection data of the target battery also indicates that a state of health is 60%, the computing device 12 determines that the difference between the health inspection data of the target battery and health data of a plurality of pre-used batteries of the uninterruptible power system is less than the preset value.

In step S154, the label printer 13 generates a label with the classification status indicating reusing, and applicable for uninterruptible power system. Specifically, for example, the state of health of the pre-used batteries in the uninterruptible power system may be 60%, and when the inspection device 11 determines that the health inspection data of the target battery indicates that the state of health of the target battery is 60%, the computing device 12 determines that the difference between the health inspection data of the target battery and health data of a plurality of pre-used batteries of the uninterruptible power system is less than the preset value, so that the label printer 13 generates a label with the classification status indicating reusing, and applicable for uninterruptible power system.

In step S156, the label printer 13 generates a label indicating the classification status of reuse. Specifically, for example, the health status of the pre-used batteries in the uninterruptible power system may be 60%. When the inspection device 11 determines that the health inspection data of the target battery indicates that the state of health is 30%, the computing device 12 determines that the difference between the health inspection data of the target battery and health data of a plurality of pre-used batteries of the uninterruptible power system is greater than the preset value, the label printer 13 generates a label with the classification status indicating reusing.

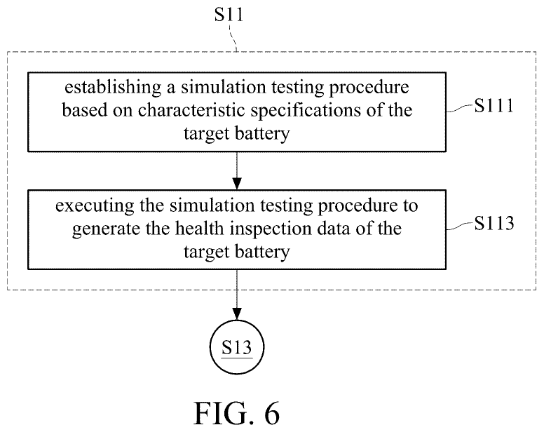

Please refer to FIG. 6, which is a flowchart illustrating inspecting a battery according to an embodiment of the present disclosure. As shown in FIG. 6, step S11 may include step S111: establishing a simulation testing procedure based on characteristic specifications of the target battery; and step S113: executing the simulation testing procedure to generate the health inspection data of the target battery. The method for inspecting a battery may be applied to the battery inspection and management system 1 shown in FIG. 1 and the battery inspection and management system 1′ shown in FIG. 2. The following description provides an example of using the battery inspection and management system 1 in FIG. 1 to explain the process depicted in FIG. 6.

In step S111, the computing device 12 establishes a simulation testing procedure based on characteristic specifications of the target battery. Specifically, the characteristic specifications of a battery may include a specification sheet provided by the client or the specification of the battery to be tested. The simulation testing procedure may be determined by using a battery management system protocol and 30 standard samples.

In step S113, the inspection device 11 executes the simulation testing procedure to generate the health inspection data of the target battery. Specifically, the health inspection data of a battery may include a battery evaluation report, the state of health, and/or the battery classification.

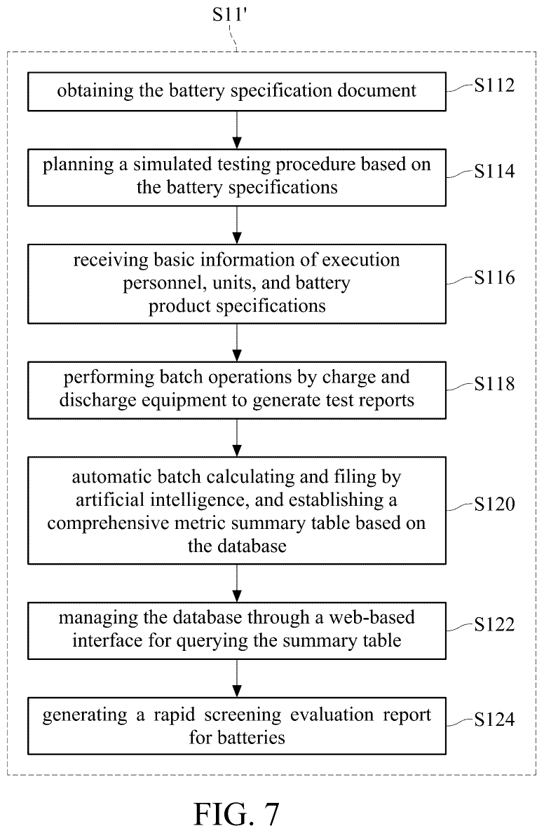

Please refer to FIG. 7, which is a flowchart illustrating inspecting a battery according to another embodiment of the present disclosure. As shown in FIG. 7, step S11′ may include step S112: obtaining the battery specification document; step S114: planning a simulated testing procedure based on the battery specifications; step S116: receiving basic information of execution personnel, units, and battery product specifications; step S118: performing batch operations by charge and discharge equipment to generate test reports; step S120: automatic batch calculating and filing by artificial intelligence, and establishing a comprehensive metric summary table based on the database; step S122: managing the database through a web-based interface for querying the summary table; and step S124: generating a rapid screening evaluation report for batteries.

In this embodiment, the battery specification obtained in step S112 may be used to plan a process simulation curve. In step S114, a testing simulation curve may be predicted, and a protective point for the battery may be set. In step S116, a basic testing information is entered. During the batch operation in step S118, charge and discharge equipment may provide a real-time display panel to show the state of the battery under test. Testing may be paused at any time by a user, and the paused process may resume in another channel for continued scheduled testing. In step S118, charge and discharge equipment also generates graphical and textual test reports to provide data for cross-referencing. In step S120, artificial intelligence (AI) is used for computation, and database files are created. In step S122, the database is managed through a summary table accessed via a web query system. In step S124, a rapid battery screening evaluation report is generated, the rapid battery screening evaluation report may include the state of health (SOH), current voltage, charging impedance, voltage drop rate, voltage recovery rate, discharge impedance, remaining available capacity, and classification grades, among others.

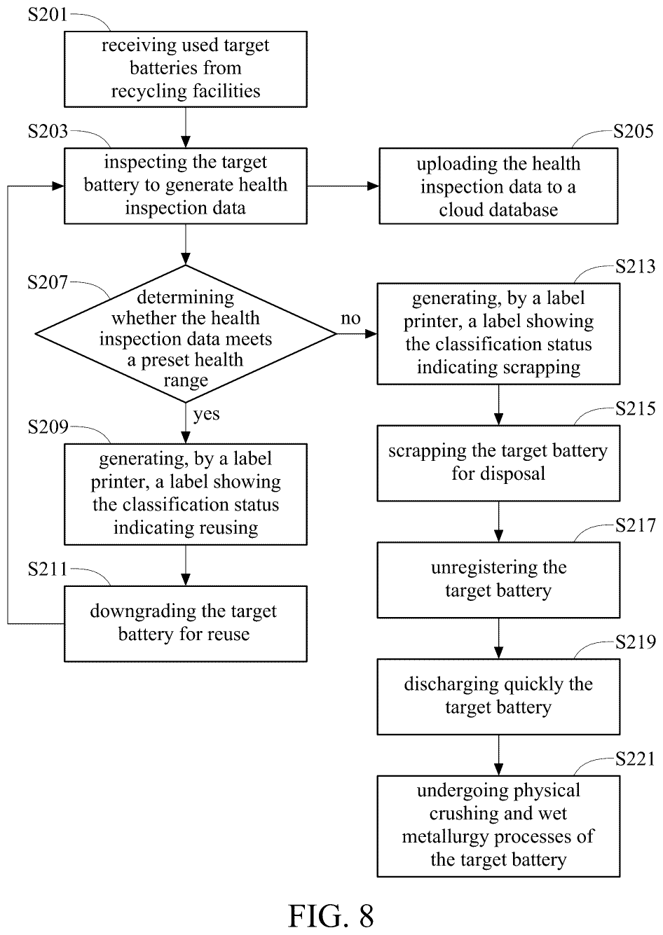

Please refer to FIG. 8, which is a flowchart illustrating a battery inspection and management method according to another embodiment of the present disclosure. As shown in FIG. 8, the battery inspection and management method may include the following steps: step S201: receiving used target batteries from recycling facilities; step S203: inspecting the target battery to generate health inspection data; step S205: uploading the health inspection data to a cloud database; step S207: determining whether the health inspection data meets a preset health range; step S209: generating, by a label printer, a label showing the classification status indicating reusing; step S211: downgrading the target battery for reuse; step S213: generating, by a label printer, a label showing the classification status indicating scrapping; step S215: scrapping the target battery for disposal; step S217: unregistering the target battery; step S219: discharging quickly the target battery; and step S221: undergoing physical crushing and wet metallurgy processes of the target battery. The battery inspection and management method may be applied to the battery inspection and management system 1 shown in FIG. 1 and the battery inspection and management system 1′ shown in FIG. 2. The battery inspection and management method shown in FIG. 8 is explained below by taking the battery inspection and management system 1 shown in FIG. 1 as an example.

In this embodiment, the used batteries are received from the recycling facilities in step S201. In step S203, the used battery is tested by the inspection device 11 to generate health inspection data, which is then uploaded to the cloud database 14 in step S205 by the computing device 12. In step S207, the computing device 12 determines whether the battery meets the preset health range based on the health inspection data. When the result is “Yes”, step S209 is performed, where the label printer 13 generates a label indicating the classification status for reuse, followed by step S211, where the battery is downgraded for reuse. The downgraded battery may be applied to energy storage cabinets, roadside equipment, or uninterruptible power systems. After reuse, step S203 and the subsequent steps may be repeated. When in step S207, the computing device 12 determines that the battery does not meet the preset health range (i.e., the result is “No”), step S213 is performed, where the label printer 13 generates a label indicating the classification status as scrapping, and continuing with scrapping the battery in step S215, deregistering the battery in S217, rapid discharge of the battery in step S219, and physically crushing and performing hydrometallurgy on the battery in step S221. Rapid discharge of the battery may be achieved by using high-frequency pulse-width modulation (PWM) or direct current internal resistance (DCIR).

In view of the above description, the battery inspection and management method and system of the present disclosure enable the sorting and labeling of the recycled battery, and the recycled battery may be reused after classifying of the recycled batteries, thereby enhancing efficiency and reducing environmental impact. Additionally, by using the rapid screening equipment and classification method, the battery inspection and management method and system of the present disclosure may save a significant amount of time and resources, allowing the data analysis of the battery management system to efficiently provide the classification and perform accurate health assessment when handling large amounts of data.

What is claimed is:

1. A battery inspection and management method, comprising:
inspecting a target battery at a first time point to generate health inspection data;
uploading the health inspection data to a cloud database;
determining a classification status of the target battery based on the health inspection data and a preset health range, and generating a label for attachment on the target battery, wherein the label shows the classification status and configured to link to the health inspection data of the target battery in the cloud database; and
inspecting the target battery at a second time point later than the first time point to update the health inspection data of the target battery in the cloud database.

2. The battery inspection and management method according to claim 1, wherein the preset health range indicates that state of health of the target battery is greater than 20%, the classification status indicates reusing when the health inspection data meets the preset health range, and the classification status indicates scrapping when the health inspection data does not meet the preset health range.

3. The battery inspection and management method according to claim 1, wherein inspecting the target battery to generate the health inspection data comprises:
establishing a simulation testing procedure based on characteristic specifications of the target battery; and
executing the simulation testing procedure to generate the health inspection data of the target battery.

4. The battery inspection and management method according to claim 1, further comprising:
marking the target battery as applicable for an uninterruptible power system when difference between the health inspection data of the target battery and health data of a plurality of pre-used batteries of the uninterruptible power system is less than a preset value.

5. The battery inspection and management method according to claim 1, wherein the label shows the classification status with different colors or patterns.

6. A battery inspection and management system, comprising:
an inspection device configured to inspect a target battery to generate health inspection data;
a computing device connected to the inspection device, configured to upload the health inspection data to a cloud database and determine a classification status of the target battery based on the health inspection data and a preset health range; and
a label printer connected to the computing device, configured to generate a label for attachment on the target battery, wherein the label shows the classification status and configured to link to the health inspection data of the target battery in the cloud database.

7. The battery inspection and management system according to claim 6, wherein the preset health range indicates that state of health of the target battery is greater than 20%, the classification status indicates reusing when the health inspection data meets the preset health range, and the classification status indicates scrapping when the health inspection data does not meet the preset health range.

8. The battery inspection and management system according to claim 6, wherein the inspection device is configured to establish a simulation testing procedure based on characteristic specifications of the target battery and to execute the simulation testing procedure to generate the health inspection data of the target battery.

9. The battery inspection and management system according to claim 6, wherein the inspection device is further configured to mark the target battery as applicable for an uninterruptible power system when difference between the health inspection data of the target battery and health data of a plurality of pre-used batteries of the uninterruptible power system is less than a preset value.

10. The battery inspection and management system according to claim 6, wherein the label shows the classification status with different colors or patterns.
